(19) United States
(12) Patent Application Publication
(10) Pub. No.: US 2022/0276292 A1
(43) Pub. Date: Sep. 1, 2022

(54) MEASUREMENT DEVICE AND MEASUREMENT METHOD

(71) Applicant: SONY GROUP CORPORATION, Tokyo (JP)

(72) Inventors: Junji MAESHIMA, Tokyo (JP); Seigo FUKUNAGA, Tokyo (JP); Yoshihiro KATO, Tokyo (JP); Kotaro FUJIMORI, Tokyo (JP)

(73) Assignee: SONY GROUP CORPORATION, Tokyo (JP)

(21) Appl. No.: 17/631,607

(22) PCT Filed: Jul. 21, 2020
(86) PCT No.: PCT/JP2020/028272

§ 371 Date: Jan. 31, 2022

(30) Foreign Application Priority Data
Aug. 7, 2019 (JP) 2019-145783

(51) Int. Cl. G01R 29/08; G01R 29/26; H04B 17/29; G01R 23/16; H04B 17/10

(52) U.S. Cl. CPC G01R 29/0871; G01R 29/26; H04B 17/29; G01R 23/16; H04B 17/10

(57) ABSTRACT

Devices and methods to allow a source of noise generated by modulation with a signal inside a device to be easily measured. A measurement device according to an embodiment includes: a transmission unit that applies a first signal formed by a high frequency signal to an object to be measured; a reception unit that receives a second signal formed by a high frequency signal generated from the object to be measured; and a measurement unit that measures the second signal received by the reception unit. The reception unit receives the second signal while the transmission unit applies the first signal.

### FIELD

The present invention relates to a measurement device and a measurement method.

### BACKGROUND

Due to a network use tendency in electronic information communication devices in recent years, a plurality of wireless functions is mounted in various devices including mobile terminals such as smartphones. Furthermore, as represented by smartphones, the scale of systems mounted in mobile terminals is increased year by year. Under such background, the need not only for supporting electromagnetic interference (EMI) that regulates an emission amount of an unnecessary electromagnetic field (noise) from an electronic device but for supporting radio frequency (RF) sensitivity deterioration in which noise in the electronic device influences wireless characteristics of the electronic device itself has been increased in recent years.

Two types (type (1) and type (2)) are known in accordance with types of noise as types in which noise influences RF sensitivity deterioration.

In the type (1), noise generated by a noise source, such as an integrated circuit (IC), of a device is generated over a wide band including an RF reception frequency band, and directly detected by an antenna of the device, which causes the RF sensitivity deterioration. In the type (2), noise generated by a noise source, such as an IC, of a device is modulated by an RF transmission wave generated inside a device. The modulated noise is generated over a band including an RF reception frequency band, and detected by an antenna of the device. This causes the RF sensitivity deterioration.

### CITATION LIST

### Patent Literature

Patent Literature 1: JP 2003-279611 A
Patent Literature 2: JP 2002-257883 A

### SUMMARY

### Technical Problem

Various techniques of measuring a noise source in the above-described type (1) have already been studied (e.g., Patent Literatures 1 and 2). Unfortunately, the techniques of measuring a noise source in the type (1) have difficulty in measuring a source of noise modulated by an RF transmission wave inside a device in the type (2).

An object of the present disclosure is to provide a measurement device and a measurement method capable of easily measuring a source of noise generated by modulation with a signal inside a device.

### Solution to Problem

For solving the problem described above, a measurement device according to one aspect of the present disclosure has a transmission unit that applies a first signal formed by a high frequency signal to an object to be measured; a reception unit that receives a second signal formed by a high frequency signal generated from the object to be measured; and a measurement unit that measures the second signal received by the reception unit, wherein the reception unit receives the second signal while the transmission unit applies the first signal.

### BRIEF DESCRIPTION OF DRAWINGS

FIG. 1A illustrates the principle of measurement according to the present disclosure.

FIG. 1B illustrates the principle of the measurement according to the present disclosure.

FIG. 2 is a block diagram schematically illustrating a configuration of one example of a measurement device according to a first embodiment.

FIG. 3 illustrates a measurement method performed by the measurement device according to the first embodiment.

FIG. 4 is a block diagram illustrating a configuration of one example of a measurement device according to a first variation of the first embodiment.

FIG. 5 is a block diagram illustrating a configuration of one example of a measurement device according to a second variation of the first embodiment.

FIG. 6A illustrates an example of a measurement result in the case where the generation and output of a transmission signal Tx performed by an SG are turned off.

FIG. 6B illustrates an example of a measurement result in the state where the generation and output of the transmission signal Tx performed by the SG are turned on and the driving of an object to be measured is turned off.

FIG. 6C illustrates an example of a measurement result in the state where the generation and output of the transmission signal Tx performed by the SG are turned on and the driving of the object to be measured is turned on.

FIG. 7 is a block diagram illustrating a configuration of one example of a measurement device according to a second embodiment.

FIG. 8 is a block diagram illustrating a configuration of one example of a PC applicable to the second embodiment.

FIG. 9 is a functional block diagram illustrating one example of the function of the PC according to the second embodiment.

FIG. 10 is a functional block diagram illustrating one example of the function of a measurement unit according to the second embodiment.

FIG. 11 is a perspective view schematically illustrating a configuration of one example of a movement device for moving the position of a probe, the movement device being applicable to the second embodiment.

FIG. 12 is a block diagram illustrating a configuration of one example of a drive unit for driving the movement device applicable to the second embodiment.

FIG. 13 is a flowchart illustrating one example of measurement processing in the measurement device according to the second embodiment.

FIG. 14 is a side view schematically illustrating a configuration example of a movement device according to another example, the movement device being applicable to the second embodiment.

FIG. 15 illustrates an example of a measurement range set as a measurement condition.

FIG. 16 illustrates an example of measurement positions in a measurement range and analysis results at the measurement positions according to the second embodiment.

FIG. 17A illustrates an example in which analysis results of regions applicable to the second embodiment are represented by densities in accordance with numerical values.

FIG. 17B illustrates an example in which analysis results of regions applicable to the second embodiment are represented by densities in accordance with numerical values.

FIG. 18A illustrates another example in which analysis results of regions applicable to the second embodiment are represented by densities in accordance with numerical values.

FIG. 18B illustrates another example in which analysis results of regions applicable to the second embodiment are represented by densities in accordance with numerical values.

FIG. 19 is a block diagram illustrating a configuration of one example of a measurement device according to a first variation of the second embodiment.

FIG. 20 is a block diagram illustrating a configuration of one example of a measurement device according to a second variation of the second embodiment.

### DESCRIPTION OF EMBODIMENTS

Embodiments of the present disclosure will be described in detail below with reference to the drawings. Note that, in the following embodiments, the same reference signs are attached to the same parts, and thereby redundant description will be omitted.

(Principle of Measurement According to Present Disclosure)

Each embodiment of the present disclosure relates to a technique of measuring noise in an electronic device. The noise causes radio frequency (RF) sensitivity deterioration that influences wireless characteristics of the electronic device.

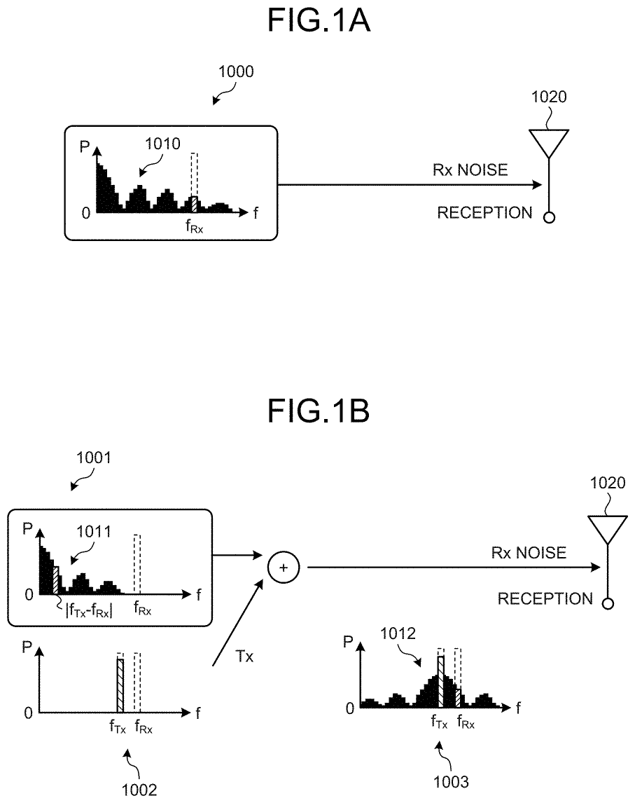

First, prior to the description of each embodiment, the principle of measurement according to the present disclosure will be schematically described in order to facilitate understanding. FIGS. 1A and 1B illustrate the principle of measurement according to the present disclosure. Note that, in each of the graphs in FIGS. 1A and 1B and each of the following similar graphs, a horizontal axis represents a frequency, and a vertical axis represents power of a signal.

Two types (type (1) and type (2)) are known in accordance with types of noise as types in which noise in an electronic device influences RF sensitivity deterioration.

FIG. 1A illustrates noise of the type (1) and RF sensitivity deterioration in an electronic device due to the noise. A graph 1000 in FIG. 1A indicates that a noise source such as an integrated circuit (IC) generates noise 1010 over a wide band including a frequency band f_{Rx} of a reception signal Rx inside a target electronic device. In the type (1), the noise 1010 is directly detected by an antenna 1020 of the electronic device, and RF sensitivity is deteriorated.

In the type (2), noise generated by a noise source including a nonlinear element such as an IC is modulated by an RF transmission wave applied to a device, the modulated noise is generated over the band including the frequency band f_{Rx} of the reception signal Rx and detected by the antenna, and the RF sensitivity is deteriorated.

Noise of the type (2) will be more specifically described with reference to FIG. 1B. A graph 1001 in FIG. 1B indicates that a noise source such as an IC generates noise 1011 over a range not including the frequency band f_{Rx} of the reception signal Rx inside a target electronic device. In the example of FIG. 1B, the noise 1011 is generated in a frequency band lower than the frequency band f_{Rx} of the reception signal Rx. In this case, the noise 1011 is not detected by the antenna 1020 of the electronic device.

When the noise source is a device mounted with a nonlinear element such as an IC and an RF transmission wave in a frequency band f_{Tx} is applied to the noise source (see graph 1002), however, intermodulation occurs. In the intermodulation, the noise 1011 generated by the noise source is modulated by the RF transmission wave. The noise modulated by the intermodulation is hereinafter referred to as modulated noise. The intermodulation generates modulated noise 1012 illustrated in a graph 1003 in FIG. 1B. In the example of the graph 1003, in relation to the modulated noise 1012, a frequency band includes the frequency band f_{Rx} of the reception signal Rx. Therefore, the modulated noise 1012 is detected by the antenna 1020 of the electronic device, and the RF sensitivity is deteriorated for the frequency band f_{Rx} of the reception signal Rx.

The intermodulation will be more specifically described. When a high frequency signal of a certain frequency f₁ is applied to a high frequency signal of another frequency f₂, the high frequency signal of the frequency f₂ is modulated by the high frequency signal of the frequency f₁, and signals of frequencies f₃ and f₄ expressed by the following expressions (1) and (2) are generated.

f₃=|f₁−f₂| (1)

f₄=f₁+f₂ (2)

In the above expressions (1) and (2), the frequency f₁ is defined as the frequency band f_{Tx} of an RF transmission wave. Furthermore, the frequency f₂ is defined as any frequency fₙₒᵢₛₑ in the noise 1011. In this case, a component at a position corresponding to a frequency |f_{Tx}−fₙₒᵢₛₑ| of the noise 1011 appears at a frequency |f_{Tx}−fₙₒᵢₛₑ| lower and a frequency (f_{TX}+fₙₒᵢₛₑ) higher than the frequency band f_{TX}. When this is applied to the entire frequency band in the noise 1011, the modulated noise 1012 in which the frequency characteristics of the noise 1011 are symmetrically developed is generated on both sides of the frequency band f_{TX} of an RF transmission wave.

Here, a component at a frequency |f_{Tx}−f_{Rx}| of the difference between the frequency band f_{Tx} of an RF transmission wave and the frequency band f_{Rx} of the reception signal Rx in the frequency fₙₒᵢₛₑ will be discussed. In the examples of the graphs 1002 and 1003, the frequency |f_{Tx}−f_{Rx}| is included in the frequency band of the noise 1011, so that the frequency |f_{Tx}−f_{Rx}| appears at a position expressed by the following expressions (3) and (4) as a component of the modulated noise 1012 in accordance with the above expressions (1) and (2).

f₅=f_{Tx}+|f_{Tx}−f_{Rx}| (3)

f₆=f_{Tx}−|f_{Tx}−f_{Rx}| (4)

The frequency f₆ among them is equal to the frequency band f_{Rx} of the reception signal Rx. For that reason, the component of the modulated noise 1012 is added to the frequency band f_{Rx} of the reception signal Rx, and the RF sensitivity for the frequency band f_{Rx} of the reception signal Rx is deteriorated.

A measurement method according to existing techniques has difficulty in measuring the modulated noise 1012 generated by the intermodulation. In the present disclosure, measurement can be made with the intermodulation occurring in a target electronic device. This facilitates identification of a source of noise caused by the intermodulation, and allows the RF sensitivity deterioration caused by the intermodulation in the electronic device to be inhibited.

### First Embodiment

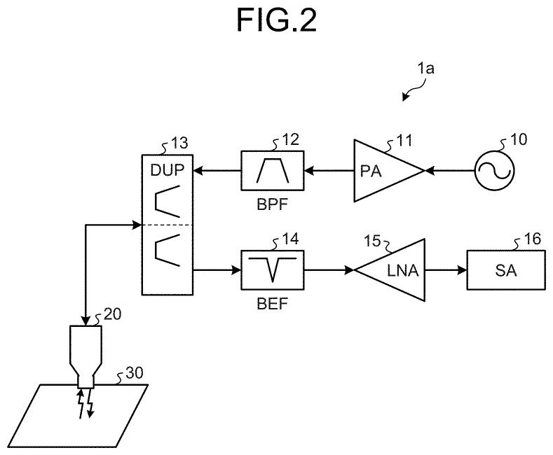

Next, a first embodiment will be described. FIG. 2 is a block diagram schematically illustrating a configuration of one example of a measurement device according to the first embodiment. In FIG. 2, a measurement device 1a includes a signal generator 10 (hereinafter, SG 10), a power amplifier 11 (hereinafter, PA 11), a band pass filter 12 (hereinafter, BPF 12), a duplexer 13 (hereinafter, DUP 13), a band elimination filter 14 (hereinafter, BEF 14), a low noise amplifier 15 (hereinafter, LNA 15), a measuring instrument (hereinafter, SA 16) 16, and a probe 20.

The SG 10 can output a high frequency signal of a desired frequency. The measurement device 1a generates and outputs a transmission signal Tx formed by a high frequency signal in the frequency band f_{Tx} to be applied to an object 30 to be measured. The transmission signal Tx generated and output by the SG 10 is a pseudo-RF transmission wave obtained by simulating an RF transmission wave to be originally received by the object 30 to be measured. The transmission signal Tx output from the SG 10 is supplied to the PA 11. The PA 11 is a power amplifier capable of high output, and amplifies and outputs the power of the transmission signal Tx supplied from the SG 10.

The BPF 12 is a filter that passes a signal of a specific frequency band and that attenuates a signal of a frequency outside the specific frequency band with steep characteristics and a high attenuation ratio. Attenuation with steep characteristics and a high attenuation ratio is hereinafter referred to as high attenuation. In this example, the BPF 12 passes a signal in the frequency band f_{Tx}, and highly attenuates signals in other frequency bands. The transmission signal Tx in the frequency band f_{Tx} output from the PA 11 passes through the BPF 12, and is supplied to the DUP 13.

The DUP 13 is a signal separator that separates two high frequency signals in different frequency bands. For example, the DUP 13 includes two band pass filters (BPFs) that pass different frequency bands. In the example of FIG. 2, one of two BPFs in the DUP 13 is used for a transmission signal that passes a high frequency signal in the frequency band f_{Tx} of the transmission signal Tx and that highly attenuates high frequency signals in other frequency bands. Furthermore, the other of the two BPFs in the DUP is used for a reception signal that passes a high frequency signal in the frequency band f_{Rx} of the reception signal Rx and that highly attenuates high frequency signals in other frequency bands.

The probe 20 is, for example, an electromagnetic field probe, and includes one probe. The probe 20 is used to apply the transmission signal Tx output from the BPF for a transmission signal of the DUP 13 to the object 30 to be measured. Furthermore, the probe 20 is also used to receive modulated noise emitted from the object 30 to be measured. That is, signal transmission and reception are performed with one common probe 20. A signal (e.g., modulated noise) received by the probe 20 is output from the probe 20, and supplied to a BPF for a reception signal of the DUP 13. The DUP 13 separates the transmission signal Tx output from the BPF 12 and the modulated noise supplied from the probe 20, and supplies the transmission signal Tx and the modulated noise to supply destinations thereof. Note that, an antenna may be used as the probe 20. Furthermore, an antenna incorporated in an electronic device such as a smartphone and a tablet personal computer to be the object 30 to be measured may be directly connected as the probe 20.

The BEF 14 highly attenuates a signal in a specific frequency band, and passes a signal in other frequency bands. In this example, the BEF 14 highly attenuates a signal in the frequency band f_{TX} corresponding to a frequency band of the transmission signal Tx, and passes signals in other frequency bands. The modulated noise supplied from the BPF for a reception signal of the DUP 13 is supplied to the BEF 14. A component of the frequency band f_{Tx} of the modulated noise is highly attenuated and output.

The modulated noise, with a highly attenuated component of the frequency band f_{TX}, output from the BEF 14 is supplied to the LNA 15. The LNA 15 is a low noise amplifier capable of amplifying a minute signal and minute noise. The modulated noise with a highly attenuated component of the frequency band f_{Tx} is amplified by the LNA 15, and supplied to the spectrum analyzer (SA) 16.

The SA 16 is a device for analyzing characteristics of a signal supplied from the LNA 15. For example, the SA 16 analyzes the supplied signal, and acquires information indicating power, a waveform, a modulation method, and the like of the signal. The SA 16 includes, for example, a display, and can display an analysis result on the display.

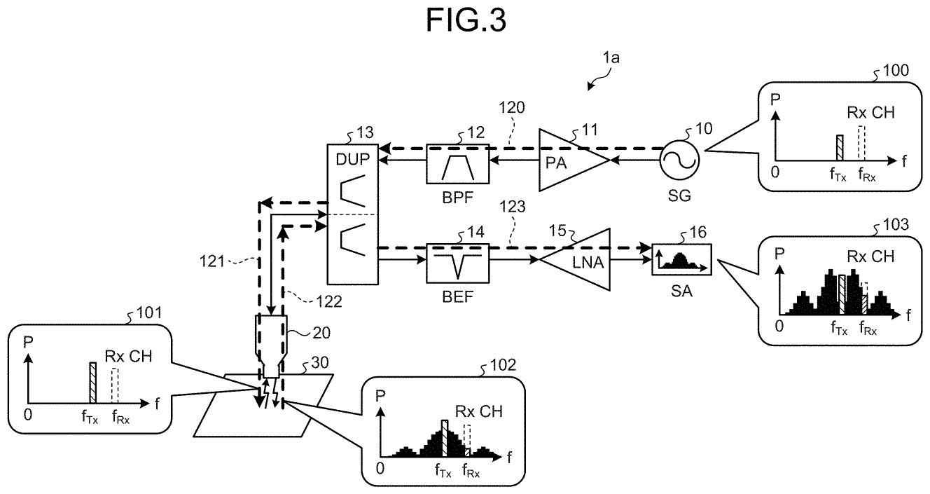

FIG. 3 illustrates a measurement method performed by the measurement device 1a according to the first embodiment. Note that the measurement device 1a has the same configuration as that described with reference to FIG. 2, and thus the detailed description thereof will be omitted here.

Note that, in FIG. 3, the object 30 to be measured is an electronic device capable of wireless communication, transmits a high frequency signal of the frequency band f_{TX}, and receives a high frequency signal of the frequency band f_{Rx} different from the frequency band f_{TX}. A smartphone, a tablet personal computer, and the like can be applied as the object 30 to be measured. The object 30 to be measured is not limited thereto. The object 30 to be measured may be an electronic device of another type as long as the electronic device includes a nonlinear element such as an IC and transmits and receives a signal based on amplitude modulation in different frequency bands and in parallel. Furthermore, frequency division duplex (FDD) is used as a communication technique applicable to the object 30 to be measured. Various possible communication methods include a universal mobile telecommunications system (UMTS), code division multiple access (CDMA), long term evolution (LTE), and the like.

At the time of measuring the object 30 to be measured, the transmission function and the reception function of the object 30 to be measured are operated.

The SG 10 generates the transmission signal Tx formed by a high frequency signal in the frequency band f_{Tx}. In FIG. 3, a graph 100 illustrates an example of the relation between the frequency band f_{TX} of the transmission signal Tx and the frequency band f_{Rx} of the reception signal Rx formed by a certain reception channel CH of the object 30 to be measured. In this example, the frequency band f_{RX} of the reception signal Rx has a frequency higher than the frequency band f_{Tx} of the transmission signal Tx.

The transmission signal Tx is input to the DUP 13 via the PA 11 and the BPF 12 along a path 120, passes through the BPF for a transmission signal of the DUP 13, and is supplied to the probe 20 (path 121). The transmission signal Tx supplied to the probe 20 is transmitted from the probe 20, and applied to the object 30 to be measured. A graph 101 illustrates an example of the transmission signal Tx applied to the object 30 to be measured. As illustrated in the graph 101, the transmission signal Tx applied to the object 30 to be measured is obtained by amplifying the power of the transmission signal Tx generated by the SG 10.

The object 30 to be measured internally includes a nonlinear element such as an IC and a large scale integration (LSI). Such nonlinear elements generate noise during operation. For example, when the object 30 to be measured transmits the transmission signal Tx in the frequency band f_{TX} from an antenna of the object 30 to be measured itself, the noise is modulated based on the transmission signal Tx by the intermodulation. This generates modulated noise corresponding to the frequency characteristics of the noise symmetrically on both sides of the frequency band f_{Tx} of the transmission signal Tx (see graph 102 in FIG. 3). When the frequency band of the modulated noise includes the frequency band f_{Rx} of the reception signal Rx of the object 30 to be measured, the RF sensitivity for the reception signal Rx is deteriorated in the object 30 to be measured.

The modulated noise propagates inside the object 30 to be measured, and is emitted to the outside of the object 30 to be measured. The modulated noise emitted to the outside is received by the probe 20. The modulated noise received by the probe 20 is input to the DUP 13 via a path 122, and supplied to the BEF 14 via a BPF for a reception signal of the DUP 13 (path 123). In the modulated noise, the frequency band f_{Tx} of the transmission signal Tx is highly attenuated in the BEF 14. The modulated noise with the frequency band f_{TX} highly attenuated by the BEF 14 is subjected to low noise amplification processing by the LNA 15, and the amplified modulated noise is supplied to the SA 16.

Here, the reception of the modulated noise performed by the probe 20 and the supply of the received modulated noise to the SA 16 via the DUP 13, the BEF 14, and the LNA 15 are performed while the transmission signal Tx is applied to the object 30 to be measured by the probe 20. In other words, the modulated noise is supplied to the SA 16 in a period that temporally overlaps the period when the probe 20 applies the transmission signal Tx to the object 30 to be measured. This allows the measurement device 1a to measure modulated noise obtained by modulating noise generated inside the object 30 to be measured based on the transmission signal Tx by the intermodulation.

Furthermore, in the modulated noise output from the DUP 13, the frequency band f_{TX} of the transmission signal Tx is highly attenuated in the BEF 14. The function of the BEF 14 inhibits a signal from going around from a transmission system (e.g., paths 120 and 121) to a reception system (path 123). That is, when the BEF 14 is not used, the power difference between the transmission signal Tx that has gone around from the transmission system to the reception system and the modulated noise received by the probe 20 may be increased. In this case, there is a possibility that the measurement result does not fall within a display range (dynamic range) on a display unit of the SA 16, for example. Attenuating the component of the frequency band f_{TX} in the BEF 14 can inhibit a peak of the component of the frequency band f_{Tx}, and avoid the state in which the measurement result does not fall within the display range.

In the example of FIG. 3, as illustrated in a graph 103, the signal level in a predetermined range centered on the frequency band f_{Tx} and the frequency band f_{Tx} of the transmission signal Tx is steeply attenuated by the BEF 14, and the entire signal level is raised by the LNA 15 as compared with the characteristics of the modulated noise in the graph 102. Increasing the overall signal level while inhibiting the peak of the frequency band fTx of the transmission signal Tx facilitates analysis, display, and the like of the SA 16.

### First Variation of First Embodiment

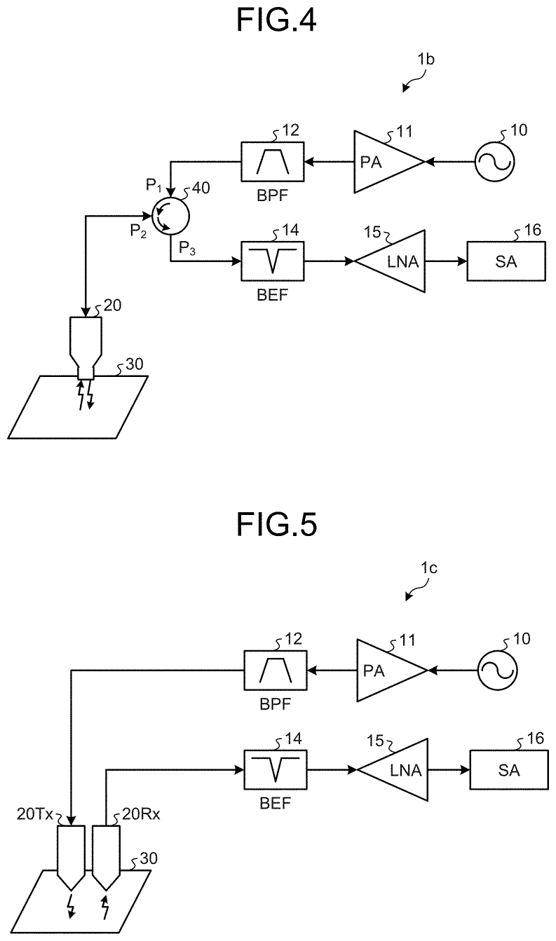

Next, a first variation of the first embodiment will be described. FIG. 4 is a block diagram illustrating a configuration of one example of a measurement device according to the first variation of the first embodiment.

A measurement device 1b according to the first variation of the first embodiment in FIG. 4 uses a circulator 40 instead of the DUP 13 in FIG. 2 as a signal separator. The signal separator separates the transmission signal Tx sent to the probe 20 and a signal received by the probe 20 and supplied from the probe 20. The circulator 40 commonly includes three ports, and has a characteristic of passing high frequency signals input to the ports only in a specific direction. The circulator can output a high frequency signal input to a certain port from a port adjacent in a specific direction. Using the characteristic of the circulator allows separation of signals.

In the example of FIG. 4, the circulator 40 has three ports P₁, P₂, and P₃. An output of the BPF 12 is connected to the port P₁ of the circulator 40. The probe 20 is connected to the port P₂ of the circulator 40. Furthermore, the BEF 14 is connected to the port P₃ of the circulator 40. The circulator 40 passes a high frequency signal in the direction of the port P₁ to the port P₂ to the port P₃ (counterclockwise in FIG. 4). The circulator 40 does not pass a high frequency signal in the opposite direction, that is, the clockwise direction in FIG. 4.

This configuration causes the output of the BPF 12 to be sent from the port P₁ of the circulator 40 to the port P₂, output from the port P₂, and supplied to the probe 20. A signal (modulated noise) output from the probe 20 is sent from the port P₂ of the circulator 40 to the port P₃, output from the port P3, and supplied to the BEF 14. In contrast, since the circulator 40 does not pass a high frequency signal in the clockwise direction in FIG. 4, the transmission signal Tx input to the port P₁ is not directly sent to the port P₃ and supplied to the BEF 14.

As compared with the above-described DUP 13, the circulator 40 has an element that distorts a high frequency signal while having no attenuation in a specific frequency band, and may itself be a noise source. Therefore, which of the DUP 13 and the circulator 40 is used as the signal separator is preferably selected appropriately based on contents required for measurement and the like.

### Second Variation of First Embodiment

Next, a second variation of the first embodiment will be described. In the first embodiment and the first variation of the first embodiment described above, the application of the transmission signal Tx to the object 30 to be measured and the reception of the modulated noise emitted from the object 30 to be measured are performed with one common probe 20. In contrast, in the second variation of the first embodiment, the application of the transmission signal Tx to the object 30 to be measured and the reception of the modulated noise emitted from the object 30 to be measured are performed with different probes.

FIG. 5 is a block diagram illustrating a configuration of one example of a measurement device according to the second variation of the first embodiment. In FIG. 5, a measurement device 1c includes two probes of a probe 20Tx and a probe 20Rx. The probe 20Tx applies the transmission signal Tx output from the BPF 12 to the object 30 to be measured. Modulated noise emitted from the object 30 to be measured by the application of the transmission signal Tx is received by the probe 20Rx, and supplied from the probe 20Rx to the BEF 14.

As described above, the measurement device 1c according to the second variation of the first embodiment performs the application of the transmission signal Tx to the object 30 to be measured and the reception of the modulated noise emitted from the object 30 to be measured with the separate probes 20Tx and 20Rx. For that reason, the measurement device 1c does not need a signal separator such as the DUP 13 and the circulator 40 described above. In contrast, when the measurement device 1c performs measurement equivalent to that performed by the measurement device 1a according to the first embodiment, the probes 20Tx and 20Rx aim at the same position of the object 30 to be measured, and the probes 20Tx and 20Rx need attention at the time of being installed.

Furthermore, in the measurement device 1c, the probes 20Tx and 20Rx can aim at different positions of the object 30 to be measured. In this case, for example, the characteristics of propagation of modulated noise between an aim position of the probe 20Tx and an aim position of the probe 20Rx can be examined.

### Specific Example of Measurement Result

Next, specific examples of measurement results in the first embodiment and variations thereof will be described. Note that, the measurement device 1b using the circulator 40 as a signal separator described with reference to FIG. 4 will be described here as an example.

In FIG. 4, in the measurement device 1b, the SG 10 generates the transmission signal Tx of a frequency of 836 [MHz], and the transmission signal Tx is supplied to the probe 20 at power of 24 [dBmW] via the PA 11, the BPF 12, and the circulator 40. The transmission signal Tx is applied to the object 30 to be measured with the probe 20 being pressed against the object 30 to be measured. The signal received by the probe 20 is supplied to the SA 16 via the circulator 40, the BEF 14, and the LNA 15. For example, the SA 16 analyzes the frequency component of the supplied signal, acquires a level of each frequency as a measurement result, and displays the acquired measurement result on a display in a graph. In the graph, the horizontal axis represents a frequency, and the vertical axis represents a level. Furthermore, the reception signal Rx has a frequency band f_{Rx} of 881 [MHz].

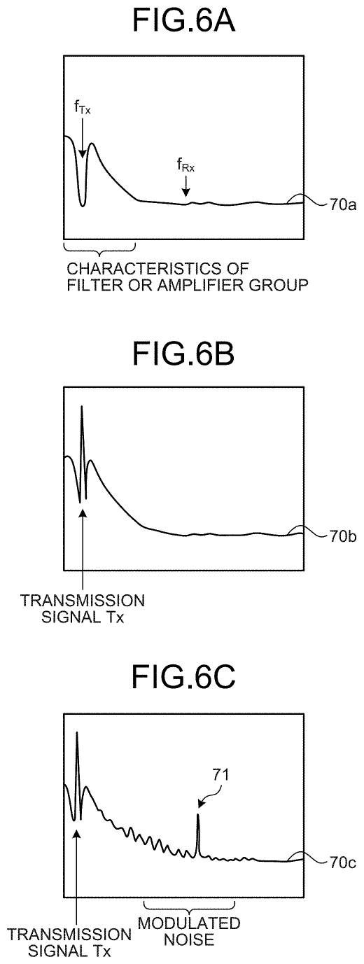

FIGS. 6A, 6B, and 6C illustrate examples of measurement results at the time when the measurement is performed by switching on/off the SG 10 and the object 30 to be measured under the above-described conditions.

FIG. 6A illustrates an example of a measurement result in the case where the generation and output of the transmission signal Tx performed by the SG 10 are turned off. Note that FIG. 6A illustrates a measurement result in the case where the driving of the object 30 to be measured is switched on/off. In a characteristic line 70a, a waveform of a peak portion appearing near the frequency f_{TX}Tx of the transmission signal Tx indicates characteristics of each filter or an amplifier group in the measurement device 1b. The characteristic indicated by the characteristic line 70a does not change in either case of the state of on or off of the object 30 to be measured. This indicates that nothing is observed even if only the driving of the object 30 to be measured, which is a noise source device, is turned on and that the object 30 to be measured alone does not generate noise up to the frequency band f_{Rx} of the reception signal Rx, for example.

FIG. 6B illustrates an example of a measurement result in the state where the generation and output of the transmission signal Tx performed by the SG 10 are turned on and the driving of the object 30 to be measured is turned off. It can be seen that, in a characteristic line 70b, a spectrum peak is observed in the frequency band f_{Tx} of the transmission signal Tx and the desired transmission signal Tx can be generated.

FIG. 6C illustrates an example of a measurement result in the state where the generation and output of the transmission signal Tx performed by the SG 10 are turned on and the driving of the object 30 to be measured is turned on. It can be seen that, in a characteristic line 70c, a peak 71 appears near the frequency band f_{Rx} of the reception signal Rx and noise that is huge to some extent is observed.

Furthermore, it can be seen that a plurality of small peaks appears in the waveforms on both sides of the frequency band f_{Rx} and the waveforms are different from those in the characteristic line 70b in FIG. 6B.

As illustrated in FIGS. 6A to 6C, no noise is observed in the operation of the object 30 to be measured alone, and no noise is observed only by the application of the transmission signal Tx to the object 30 to be measured. In contrast, the noise in FIG. 6C is observed with the object 30 to be measured being driven and the transmission signal Tx being applied to the object 30 to be measured. These facts indicate that the noise is intended modulated noise. The above description indicates that modulated noise can be measured by using the technology of the present disclosure.

As described above, according to the first embodiment and variations thereof, it is possible to measure modulated noise generated by the intermodulation in the object 30 to be measured mounted with a nonlinear element. Furthermore, according to the first embodiment and variations thereof, a system for measuring the modulated noise can be constructed by utilizing an existing device, leading to excellent cost performance.

### Second Embodiment

Next, a second embodiment of the present disclosure will be described. In the second embodiment, the above-described probe 20 is moved in the vicinity of the object 30 to be measured, which allows the object 30 to be measured to be scanned. Automatic scanning of the object 30 to be measured with the probe 20 allows distribution of modulated noise in the object 30 to be measured to be easily measured.

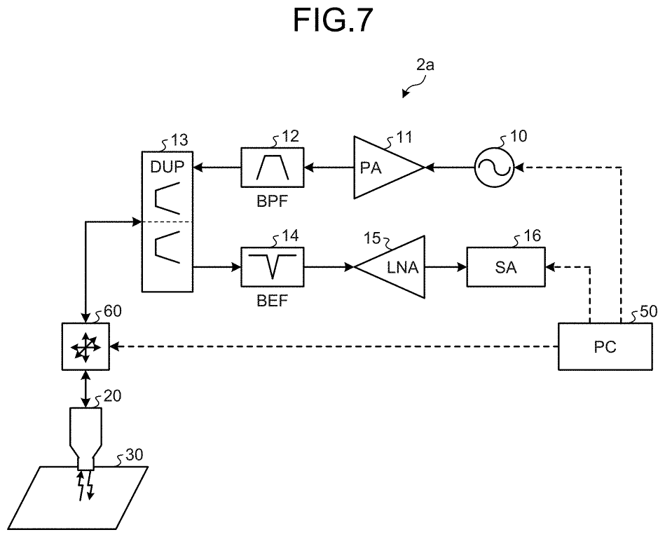

FIG. 7 is a block diagram illustrating a configuration of one example of a measurement device according to the second embodiment. In FIG. 7, a measurement device 2a is obtained by adding a positioner 60 and a personal computer 50 (hereinafter, PC 50) to the measurement device 1a in FIG. 2. The probe 20 is attached to the positioner 60. The positioner 60 includes a mechanism for moving the probe 20 in a horizontal plane (X-axis and Y-axis) and vertical direction (Z-axis direction). The PC 50 synchronously controls the operation of the positioner 60 and the operations of the SG 10 and a measuring instrument 16.

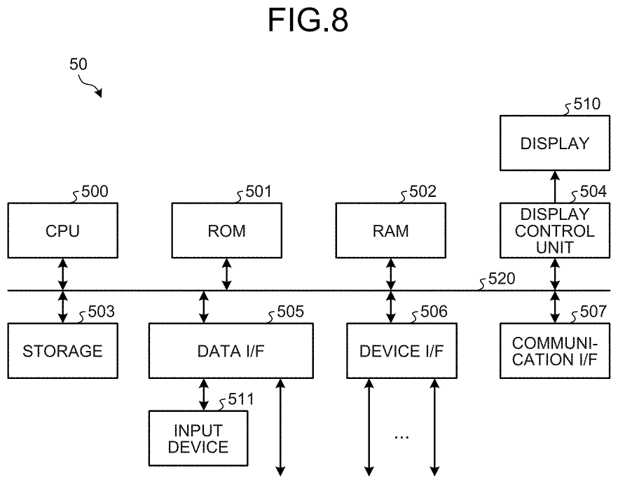

FIG. 8 is a block diagram illustrating a configuration of one example of the PC 50 applicable to the second embodiment. In FIG. 8, the PC 50 includes a central processing unit (CPU) 500, a read only memory (ROM) 501, a random access memory (RAM) 502, a storage 503, a display control unit 504, a data I/F 505, a device I/F 506, and a communication I/F 507, which are connected so as to communicate with each other by a bus 520.

The storage 503 is a nonvolatile storage medium such as a hard disk drive and a flash memory, and can store programs and data for the CPU 500 to operate. The CPU 500 uses the RAM 502 as a work memory to control the overall operation of the PC 50 in accordance with a program preliminarily stored in the storage 503 and the ROM 501.

A display 510 is connected to the display control unit 504. The display control unit 504 generates a display signal capable of being displayed by the display 510 based on a display control signal generated by the CPU 500 in accordance with a program. The display control unit 504 supplies the generated display signal to the display 510. The display 510 displays a screen in accordance with a display signal supplied from the display control unit 504.

The data I/F 505 is an interface for transmitting and receiving data and control signals to and from an external device. For example, a universal serial bus (USB) can be applied as the data I/F 505. Furthermore, a pointing device such as a mouse and an input device 511 such as a keyboard can be connected to the data I/F 505. The input device 511 generates a control signal in accordance with a user operation. The control signal is passed to the CPU 500 via the data I/F 505.

The device I/F 506 is an interface for connection to the SG 10, the SA 16, and the positioner 60. The CPU 500 generates a control signal for controlling the SG 10, the SA 16, and the positioner 60 in accordance with a program, and supplies the generated control signal to the SG 10, the SA 16, and the positioner 60 via the device I/F 506. Furthermore, status information and the like output from the SG 10, the SA 16, and the positioner 60 are passed to the CPU 500 via the device I/F 506. A measurement result from the SA 16 may be passed to the CPU 500 via the device I/F 506. This is not a limitation, and the measurement result from the SA 16 may be passed to the CPU 500 via the data I/F 505.

The communication I/F 507 controls communication with a network such as a local area network (LAN).

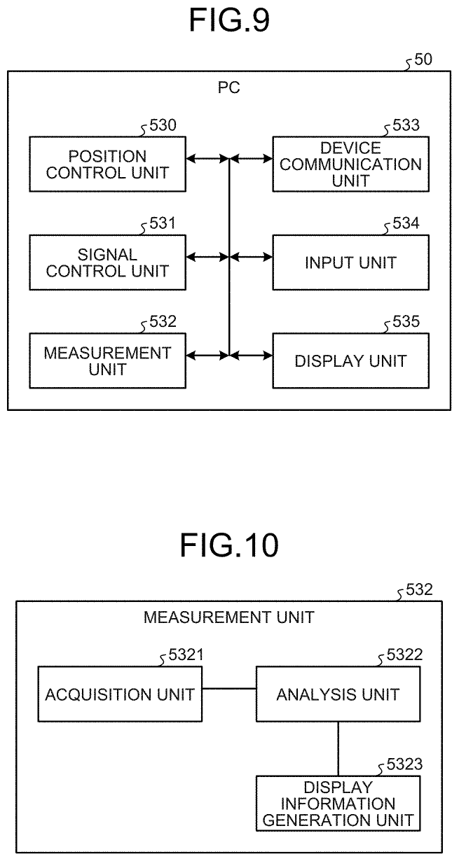

FIG. 9 is a functional block diagram illustrating one example of the function of the PC 50 according to the second embodiment. In FIG. 9, the PC 50 includes a position control unit 530, a signal control unit 531, a measurement unit 532, a device communication unit 533, an input unit 534, and a display unit 535. The position control unit 530, the signal control unit 531, the measurement unit 532, the device communication unit 533, the input unit 534, and the display unit 535 are achieved by a measurement program that operates on the CPU 500. This is not a limitation, and a part or all of the position control unit 530, the signal control unit 531, the measurement unit 532, the device communication unit 533, the input unit 534, and the display unit 535 may be configured by hardware circuits that operate in cooperation with each other.

The position control unit 530 generates a movement control signal for controlling movement of the positioner 60 in the X-axis, Y-axis, and Z-axis directions. The signal control unit 531 generates a signal control signal for controlling generation of the transmission signal Tx performed by the SG 10. The measurement unit 532 generates a measurement control signal for controlling the operation of the SA 16. Furthermore, the measurement unit 532 acquires a measurement result from the SA 16, and also analyzes the acquired measurement result. The device communication unit 533 controls the device I/F 506, and communicates with the SG 10, the SA 16, and the positioner 60. Each of the movement control signal, the signal control signal, and the measurement control signal is transmitted to each of the positioner 60, the SG 10, and the SA 16 by the device communication unit 533.

The input unit 534 receives input made to the input device 511, and causes the PC 50 to execute a predetermined operation based on a control signal in accordance with the received input. The display unit 535 generates a display control signal for performing predetermined display. The generated display control signal is passed to the display control unit 504.

FIG. 10 is a functional block diagram illustrating one example of the function of the measurement unit 532 according to the second embodiment. In FIG. 10, the measurement unit 532 includes an acquisition unit 5321, an analysis unit 5322, and a display information generation unit 5323.

The acquisition unit 5321 acquires a measurement result from the SA 16 at predetermined timing. For example, the acquisition unit 5321 acquires the measurement result from the SA 16 in synchronization with the position control of the positioner 60 performed by the position control unit 530 and the control of generation of the transmission signal Tx performed by the signal control unit 531. For example, the acquisition unit 5321 acquires information indicating a frequency and information indicating a level at the frequency in association with each other from the SA 16. Furthermore, the acquisition unit 5321 can acquire position information corresponding to the information indicating a frequency and the information indicating a level from the position control unit 530.

The analysis unit 5322 analyzes the measurement result acquired by the acquisition unit 5321. For example, when the acquired measurement result includes a plurality of pieces of information indicating a level, the analysis unit 5322 can obtain a statistical value such as an average value of a plurality of levels as an analysis result. This is not a limitation, and, when the acquired measurement result includes a plurality of sets of the information indicating a frequency and the information indicating a level, the analysis unit 5322 can obtain a desired statistical value such as an average and dispersion of a level as an analysis result. The analysis unit 5322 passes the analysis result based on the measurement result to the display information generation unit 5323 in association with the position information acquired by the acquisition unit 5321.

The display information generation unit 5323 generates display information for displaying a screen based on the analysis result and the position information passed from the analysis unit 5322 on the display 510 or the like. The display information generation unit 5323 can generate display information for displaying the analysis result and the position information in a list, for example.

Furthermore, the display information generation unit 5323 can display the analysis result by generating a map based on the corresponding position information. In the case, the display information generation unit 5323 can generate a map in which the analysis result is displayed as a numerical value based on the position information. Furthermore, the display information generation unit 5323 can display the analysis result in a map as image information such as density (color density, light and dark of color) corresponding to the value of the analysis result.

Moreover, the display information generation unit 5323 can further display an image indicating a boundary corresponding to the analysis result on the map for displaying the analysis result based on the position information. Moreover, the display information generation unit 5323 can preliminarily acquire an image of a surface to be measured of the object 30 to be measured, and display the image by superimposing the image on the map.

The measurement program for executing the processing according to the second embodiment has a module configuration including, for example, the above-described units (position control unit 530, signal control unit 531, measurement unit 532, device communication unit 533, input unit 534, and display unit 535). As actual hardware, the CPU 500 reads the measurement program from the storage 503, and executes the program. The above-described units are thereby loaded on a main storage device (e.g., RAM 502), and generated on the main storage device.

### Positioner Applicable to Second Embodiment

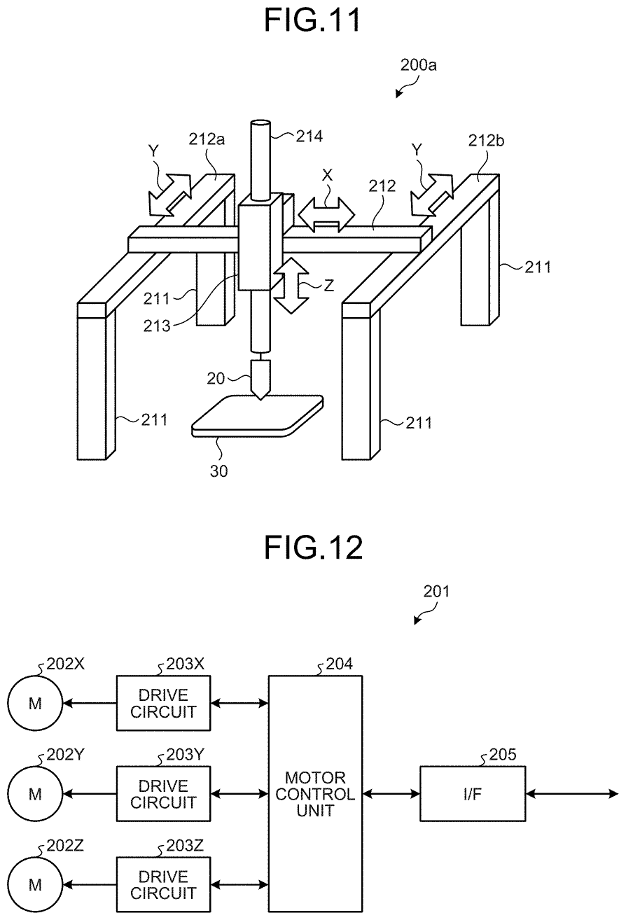

Next, the positioner 60 applicable to the second embodiment will be schematically described. FIGS. 11 and 12 illustrate a configuration of one example of the positioner 60 applicable to the second embodiment. FIG. 11 is a perspective view schematically illustrating a configuration of one example of a movement device 200a for moving the position of the probe 20, the movement device 200a being applicable to the second embodiment. FIG. 12 is a block diagram illustrating a configuration of one example of a drive unit 201 for driving the movement device 200a in FIG. 11. The positioner 60 includes the movement device 200a and the drive unit 201.

Note that, in FIG. 11, a vertical direction in the figure is defined as a Z-axis, a horizontal direction in the figure is defined as an X-axis, and a direction from diagonally upper right to diagonally lower left is defined as a Y-axis.

In the example of FIG. 11, the movement device 200a includes four legs 211, horizontal movement portions 212, 212a, and 212b, a vertical movement portion 213, and a probe support portion 214. The four legs 211 constitute pedestals. The horizontal movement portions 212a and 212b are provided on the pedestals along the Y-axis direction. The horizontal movement portion 212 is provided so as to move in the Y-axis direction with respect to the horizontal movement portions 212a and 212b. The vertical movement portion 213 is provided so as to move in the X-axis direction with respect to the horizontal movement portion 212. Moreover, the vertical movement portion 213 can move in the Z-axis direction with respect to the horizontal movement portion 212. The probe support portion 214 is provided through the vertical movement portion 213. The probe 20 is provided at the lower end of the probe support portion 214.

The probe 20 can freely move within a predetermined range of the horizontal movement portions 212, 212a, and 212b in the X-axis and Y-axis directions, and can freely move within a predetermined range of the vertical movement portion 213 in the Z-axis direction. This allows the probe 20 to freely move within a predetermined range on a two-dimensional plane on the horizontally installed object 30 to be measured.

In FIG. 12, the drive unit 201 includes motors 202X, 202Y, and 202Z, drive circuits 203X, 203Y, and 203Z, a motor control unit 204, and an interface (I/F) 205.

The motor 202X moves the vertical movement portion 213 in the X-axis direction, and is provided inside the vertical movement portion 213, for example. The motor 202Y moves the vertical movement portion 213 in the Y-axis direction, and is provided inside the horizontal movement portion 212, for example. Furthermore, the motor 202Z moves the vertical movement portion 213 in the Z-axis direction, and is provided inside the vertical movement portion 213, for example.

The drive circuits 203X, 203Y, and 203Z respectively drives the motors 202X, 202Y, and 202Z on a one-to-one basis under the control of the motor control unit 204. In the motor control unit 204, a control signal for changing the position of the probe 20 transmitted from the device I/F 506 of the PC 50 is received by the I/F 205, and passed to the motor control unit 204. The motor control unit 204 generates drive control signals for driving the motors 202X, 202Y, and 202Z based on the control signal, and supplies the generated drive control signals to the drive circuits 203X, 203Y, and 203Z. The drive circuits 203X, 203Y, and 203Z respectively drive the motors 202X, 202Y, and 202Z in accordance with the passed drive control signals.

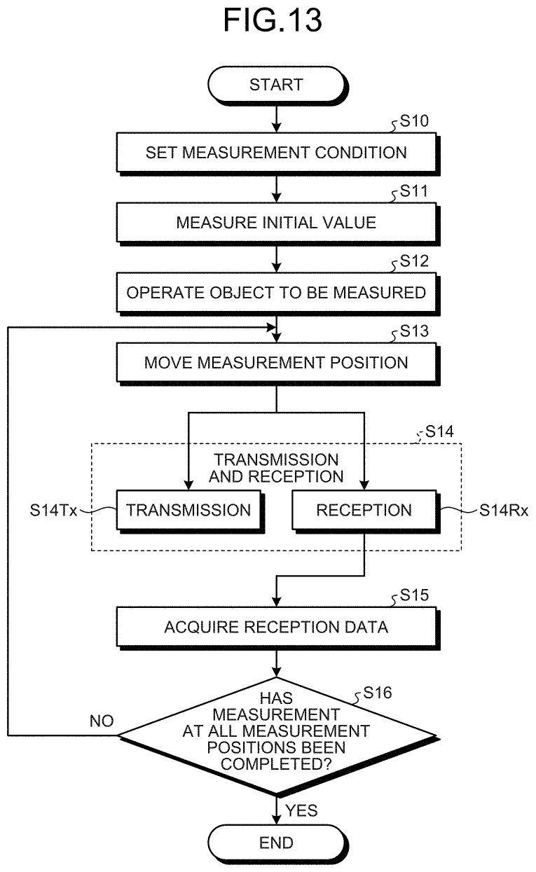

FIG. 13 is a flowchart illustrating one example of measurement processing in the measurement device 2a according to the second embodiment. Note that the object 30 to be measured is preliminarily installed at a predetermined position with respect to the movement device 200a. Furthermore, the object 30 to be measured is powered off and not operating in an initial state.

In Step S10, for example, a user inputs a measurement condition to the PC 50, and sets the measurement condition to the measurement device 2a. The measurement condition includes, for example, a frequency band f_{Tx} of the transmission signal Tx, a frequency band f_{Rx} of the reception signal Rx, and a signal level of the transmission signal Tx applied to the object 30 to be measured by the probe 20. The measurement condition further includes coordinate information indicating a measurement range of the object 30 to be measured and information indicating a measurement position in the measurement range (e.g., information indicating number of measurement points and coordinates of each measurement position). The set measurement condition is stored in, for example, the RAM 502 or the storage 503.

In next Step S11, measurement based on an initial value is performed. For example, the position control unit 530 controls the positioner 60 to move the position of the probe 20 to an initial position. The signal control unit 531 controls the SG 10 so that the SG 10 does not output the transmission signal Tx. The measurement unit 532 acquires a signal received from the probe 20, analyzes the acquired signal, and holds an analysis result.

In next Step S12, for example, the object 30 to be measured is powered on to operate the object 30 to be measured. The processing in Step S12 is executed by the user operating the object 30 to be measured, for example.

When the object 30 to be measured is operated, the processing proceeds to Step S13. For example, after the object 30 to be measured is operated in Step S12, the user performs a predetermined operation on the PC 50, for example. This causes the processing to proceed to Step S13.

In Step S13, the position control unit 530 controls the movement device 200a in accordance with the measurement condition set in Step S10 to move the probe 20 to a predetermined position. In next Step S14, transmission and reception processing, that is, transmission of the transmission signal Tx and reception of a signal emitted from the object 30 to be measured are performed.

More specifically, the signal control unit 531 controls the SG 10 to output the transmission signal Tx (Step S14Tx). This causes the transmission signal Tx to be supplied to the probe 20 via the PA 11, the BPF 12, and the DUP 13, and causes the transmission signal Tx to be applied to the object 30 to be measured. Furthermore, in Step S14Rx, the probe 20 receives a signal emitted from the object 30 to be measured. The processing in Step S14Rx is executed while the transmission signal Tx is applied to the object 30 to be measured in Step S14Tx.

In next Step S15, the SA 16 acquires the signal received by the probe 20 in Step S14Rx via the DUP 13, the BEF 14, and the LNA 15. The SA 16 generates a measurement result based on the acquired signal, and sends the generated measurement result to the PC 50. In the PC 50, the measurement unit 532 acquires the measurement result sent from the SA 16, and stores the measurement result in, for example, the RAM 502.

In next Step S16, the position control unit 530 determines whether or not the measurement at all the measurement positions set under the measurement condition in Step S10 has been completed. When it is determined that the measurement has not been completed (Step S16, “No”), the processing returns to Step S13, and the processing at the next measurement position is started. When it is determined that the processing has been completed (Step S16, “Yes”), a series of pieces of processing according to the flowchart of FIG. 13 is completed.

Note that, when the series of pieces of processing according to the flowchart of FIG. 13 is completed, the measurement unit 532 causes the analysis unit 5322 to analyze the measurement result acquired in Step S15 and stored in the RAM 502, and causes the display information generation unit 5323 to generate display information based on the analysis result.

As described above, in the second embodiment, the positioner 60 allows the probe 20 to move in a two-dimensional plane on the object 30 to be measured and the operation of sequentially changing a measurement position to be executed under automatic control. For that reason, distribution of the emission amount of modulated noise on the surface of the object 30 to be measured can be easily grasped.

### Another Example of Movement Device

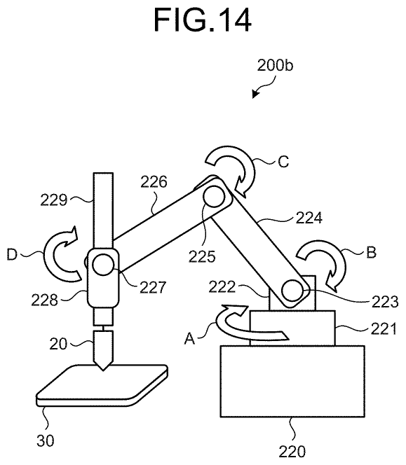

Next, an example in which the movement device that moves the probe 20 is achieved by a configuration different from that of the movement device 200a in FIG. 11 will be described. FIG. 14 is a side view schematically illustrating a configuration example of a movement device 200b according to another example, the movement device 200b being applicable to the second embodiment. In FIG. 14, the movement device 200b includes a rotation table 221 and arm portions 224, 226, and 228. The rotation table 221 rotates on a horizontal plane of a pedestal 220. The arm portions 224, 226, and 228 are rotated in a plane perpendicular to the horizontal plane of the pedestal by joint portions 223, 225, and 227.

The rotation table 221 is provided on the pedestal 220, and one end of the arm portion 224 is connected to a protrusion 222 provided on the rotation table 221 by the joint portion 223. The other end of the arm portion 224 is connected to one end of the arm portion 226 by the joint portion 225. The other end of the arm portion 226 is connected to one end of the arm portion 228 by the joint portion 227. A probe support portion 229 is provided on the arm portion 228. The probe 20 is attached on the other end side of the arm portion 228 by the probe support portion 229. Furthermore, a motor driven and controlled in accordance with a control signal from the PC 50 is provided in the rotation table 221 and each of the joint portions 223, 225, and 227.

In such a configuration, the rotation table 221 can be rotated in the horizontal plane of the pedestal 220 as indicated by an arrow A in FIG. 14. Furthermore, each of the joint portions 223, 225, and 227 can be rotated in a plane perpendicular to the horizontal plane of the pedestal 220 as indicated by arrows B, C, and D in FIG. 14. This allows the probe 20 to freely move within a predetermined range on a two-dimensional plane on the horizontally installed object 30 to be measured while keeping a vertical posture.

### Display Example of Measurement Result According to Second Embodiment

Next, a display example of a measurement result (analysis result) according to the second embodiment will be described. FIG. 15 illustrates an example of a measurement range set as a measurement condition in Step S10 of the flowchart of FIG. 13. In the example of FIG. 15, the object 30 to be measured is a smartphone. A receiver 301, a camera 302, and the like are disposed at the upper portion in FIG. 15. A screen 300 is disposed in the central portion. An operator and the like (not illustrated) for performing main operations on a transmitter and the smartphone are disposed in a lower region 303. In the example of FIG. 15, a measurement range 310 includes the entire area of the screen 300, parts of the receiver 301 and the camera 302, and a part of the region 303.

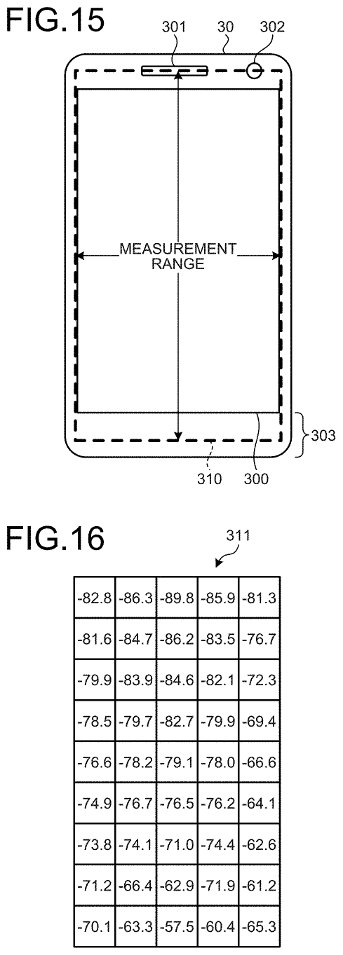

FIG. 16 illustrates an example of measurement positions in the measurement range 310 and analysis results at the measurement positions according to the second embodiment. Note that FIG. 16 illustrates an example of an analysis result screen 311 in which the analysis results at the measurement positions are displayed as numerical values.

In the example of FIG. 16, the measurement range 310 is divided into five in the horizontal direction and nine in the vertical direction, and is thus divided into 45 regions. It is conceivable that the measurement positions are set to be, for example, central portions of the regions. Furthermore, the numerical value of the analysis result in each region means an average value of signal levels in each region (each measurement position).

When the analysis result of each region is expressed by, for example, an image differently displayed in accordance with a numerical value, the measurement result can be more intuitively grasped.

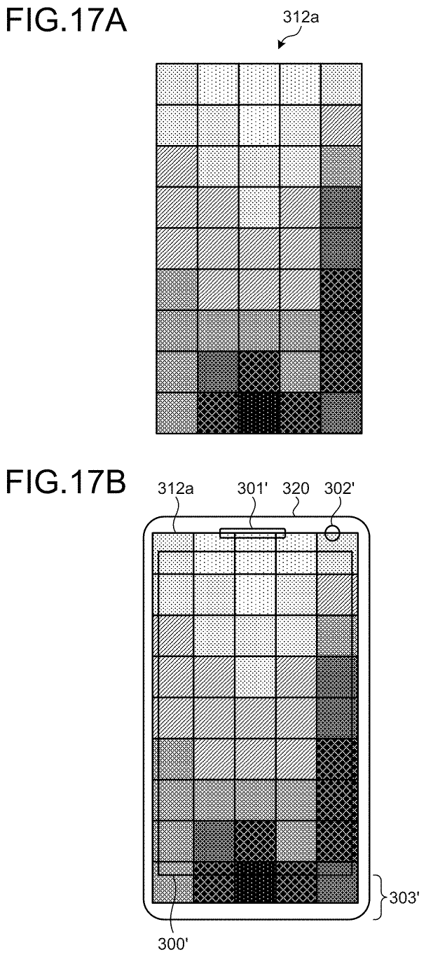

FIGS. 17A and 17B illustrate examples in which analysis results of regions applicable to the second embodiment are represented by densities in accordance with numerical values. In an analysis result screen 312a in FIG. 17A, boundaries between regions are displayed. As a numerical value of a region is increased, the density displayed in the region is increased. In the example of FIG. 17A, it can be seen that the central region at the lowermost stage has the highest density and has a larger numerical value, that is, has a large emission amount of modulated noise. Furthermore, specifically, a central region at the uppermost stage has a lower density and a smaller numerical value than other regions. That is, it can be seen that the emission amount of modulated noise is small.

FIG. 17B illustrates an example in which an image 320 of the object 30 to be measured is superimposed and displayed on the analysis result screen 312a in FIG. 17A. In FIG. 17B, the outline of the object 30 to be measured is clearly displayed. An image 300′ of the screen, an image 301′ of the receiver, an image 302′ of the camera, and a region 303′ corresponding to the region 303 in FIG. 15 are superimposed and displayed on the analysis result screen 312a. As a result, it is possible to intuitively grasp at which position of the object 30 to be measured the emission amount of modulated noise is increased. For example, it can be estimated that an element serving as a noise source of modulated noise is disposed in a central portion on the lower end side of the object 30 to be measured.

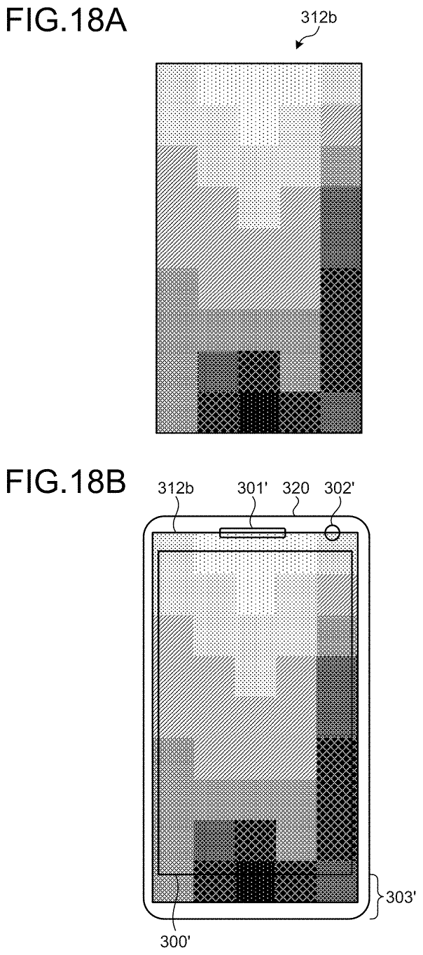

FIGS. 18A and 18B illustrate other examples in which analysis results of regions applicable to the second embodiment are represented by densities in accordance with numerical values. Similarly to the case of FIG. 17A, in an analysis result screen 312b in FIG. 18A, as a numerical value of a region is increased, the density displayed in the region is increased. In this case, the analysis result screen 312b gradationally displays analysis results as a whole without clearly indicating boundaries between regions. If boundaries between regions are displayed in the case where the measurement range 310 has a number of divisions and each region has a small area, the screen may be complicated. Distribution of the emission amount of modulated noise can be more easily grasped by not displaying the boundaries between regions as in FIG. 18A.

FIG. 18B illustrates an example in which the image 320 of the object 30 to be measured is superimposed and displayed on the analysis result screen 312b in FIG. 18A. Similarly to the case in FIG. 17B, the image 300′ of the screen, the image 301′ of the receiver, the image 302′ of the camera, and the region 303′ corresponding to the region 303 in FIG. 15 are superimposed and displayed on the analysis result screen 312b. Since the boundaries between regions are not displayed, the relation between the distribution of the emission amount of modulated noise and each component of the object 30 to be measured can be more easily grasped.

### First Variation of Second Embodiment

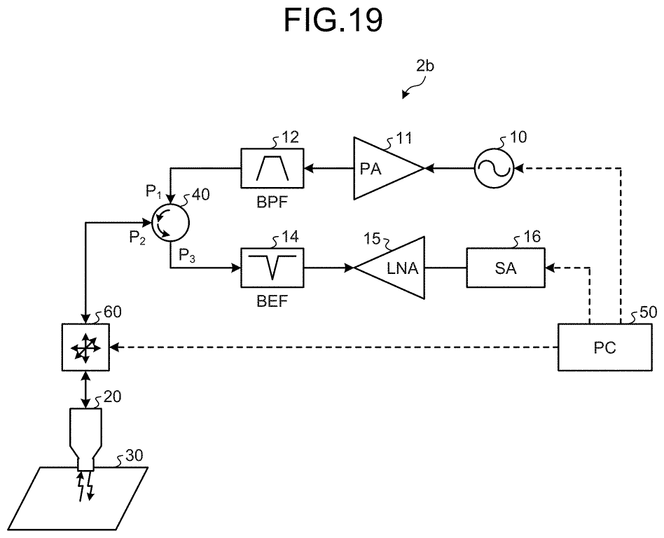

Next, a first variation of the second embodiment will be described. FIG. 19 is a block diagram illustrating a configuration of one example of a measurement device according to the first variation of the second embodiment.

Similarly to the first variation of the first embodiment illustrated with reference to FIG. 4, a measurement device 2b according to the first variation of the second embodiment in FIG. 19 uses the circulator 40 instead of the DUP 13 in FIG. 7 as a signal separator. The signal separator separates the transmission signal Tx sent to the probe 20 and a signal received by the probe 20 and supplied from the probe 20. Other configurations are similar to those of the measurement device 2a in FIG. 7, and thus the description thereof is omitted here.

Also in the configuration in FIG. 19, similarly to the above-described configuration in FIG. 7, an operation of moving the probe 20 in a two-dimensional plane on the object 30 to be measured with the positioner 60 and sequentially changing a measurement position can be executed under the automatic control. For that reason, distribution of the emission amount of modulated noise on the surface of the object 30 to be measured can be easily grasped.

### Second Variation of Second Embodiment

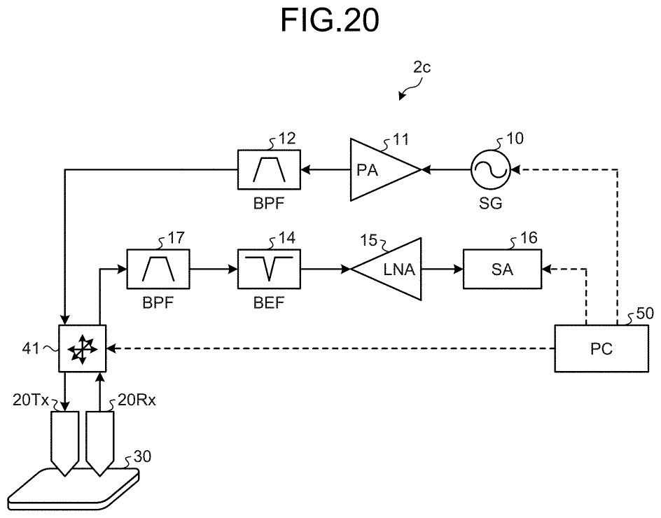

Next, a second variation of the second embodiment will be described. FIG. 20 is a block diagram illustrating a configuration of one example of a measurement device according to the second variation of the second embodiment.

Similarly to the second variation of the first embodiment described with reference to FIG. 5, a measurement device 2c according to the second variation of the second embodiment in FIG. 20 applies the transmission signal Tx to the object 30 to be measured with the probe 20Tx, and receives modulated noise emitted from the object 30 to be measured with the probe 20Rx different from the probe 20Tx.

In FIG. 20, a positioner 61 can individually move the two probes 20Tx and 20Rx. For example, in the configuration of FIG. 11, it is conceivable to provide two sets of the horizontal movement portions 212, 212a, and 212b and the vertical movement portion 213 in different stages. In the example of FIG. 14, it is conceivable to simply arrange and install two movement devices 200b.

Furthermore, in the example of FIG. 20, a signal output from the probe 20Rx for reception is supplied to the BEF 14 via a BPF 17. For example, a BPF that passes a high frequency signal in the frequency band f_{Rx} of the reception signal Rx and highly attenuates high frequency signals in other frequency bands is used as the BPF 17.

The measurement device 2c according to the second variation of the second embodiment can individually control the positions of the probes 20Tx and 20Rx under the automatic control. Therefore, when the probes 20Tx and 20Rx aim at different positions of the object 30 to be measured, more complicated movement of a measurement position can be more easily achieved. For example, it is possible to more easily achieve control in which the position of the probe 20Tx is fixed, the probe 20Rx is moved to perform measurements at measurement positions in the measurement range 310, the position of the probe 20Tx is moved and fixed after the probe 20Rx completes the measurements at all the measurement positions, and the probe 20Rx is moved again to perform measurements at the measurement positions in the measurement range 310. This allows more detailed investigation of characteristics of propagation between an aim position of the probe 20Tx and an aim position of the probe 20Rx to be easily executed.

As described above, when the two probes 20Tx and 20Rx whose movement can be individually controlled are used, a method of performing measurement by moving only at least one of the probes 20Tx and 20Rx is also effective.

Note that the effects set forth in the specification are merely examples and not limitations. Other effects may be exhibited.

Note that the present technology can also have the configurations as follows.

(1) A measurement device comprising:

a transmission unit that applies a first signal formed by a high frequency signal to an object to be measured;

a reception unit that receives a second signal formed by a high frequency signal generated from the object to be measured; and

a measurement unit that measures the second signal received by the reception unit,

wherein the reception unit receives the second signal while the transmission unit applies the first signal.

(2) The measurement device according to the above (1),

wherein application of the first signal performed by the transmission unit and reception of the second signal performed by the reception unit are performed with one common probe.

(3) The measurement device according to the above (2), further comprising

a signal separation unit that separates the first signal and the second signal,

supplying the first signal to the probe via the signal separation unit, and

supplying the second signal output from the probe to the reception unit via the signal separation unit.

(4) The measurement device according to the above (3),

wherein the signal separation unit is a duplexer.

(5) The measurement device according to the above (3),

wherein the signal separation unit is a circulator.

(6) The measurement device according to the above (1),

wherein a probe used for application of the first signal performed by the transmission unit is different from a probe used for reception of the second signal performed by the reception unit.

(7) The measurement device according to any one of the above (1) to (6),

wherein the reception unit receives the second signal including modulated noise obtained by modulating noise generated inside the object to be measured by the first signal, which has been applied to the object to be measured by the transmission unit.

(8) The measurement device according to any one of the above (1) to (7), further comprising

a movement control unit that moves at least one of a position where the transmission unit applies the first signal to the object to be measured and a position where the reception unit receives the second signal,

wherein the movement control unit sequentially changes the measurement position in a two-dimensional plane on the object to be measured.

(9) The measurement device according to the above (8),

wherein the measurement unit displays information indicating the second signal measured at the measurement position on a display unit in association with the measurement position.

(10) The measurement device according to the above (9).

wherein the measurement unit displays each piece of information indicating the second signal associated with each measurement position on the display unit in association with each measurement position by using a map of the two-dimensional plane.

(11) The measurement device according to the above (10),

wherein the measurement unit displays each piece of information indicating the second signal on the display unit by using the map using an image representing a density corresponding to information indicating the second signal.

(12) The measurement device according to the above (10),

wherein the measurement unit superimposes information indicating a boundary on the two-dimensional plane corresponding to each measurement position on the map, and displays the information on the display unit.

(13) The measurement device according to the above (10),

wherein the measurement unit superimposes an image of the object to be measured on the map, and displays the image on the display unit.

(14) A measurement method comprising:

while a transmission unit applies a first signal formed by a high frequency signal to an object to be measured,

a reception unit receiving a second signal formed by a high frequency signal generated from the object to be measured; and

a measurement unit measuring the received second signal.

### REFERENCE SIGNS LIST

1a, 1b, 1c, 2a, 2b, 2c MEASUREMENT DEVICE
10 SG
11 PA
12, 17 BPF
13 DUP
14 BEF
15 LNA
16 SA
20, 20Tx, 20Rx PROBE
30 OBJECT TO BE MEASURED
40 CIRCULATOR
50 PC
60, 61 POSITIONER
200a, 200b MOVEMENT DEVICE
310 MEASUREMENT RANGE
312a, 312b ANALYSIS RESULT SCREEN
530 POSITION CONTROL UNIT
531 SIGNAL CONTROL UNIT
532 MEASUREMENT UNIT
5321 ACQUISITION UNIT
5322 ANALYSIS UNIT
5323 DISPLAY INFORMATION GENERATION UNIT

What is claimed is:

1. A measurement device, comprising:
a transmission unit that applies a first signal formed by a high frequency signal to an object to be measured;
a reception unit that receives a second signal formed by a high frequency signal generated from the object to be measured; and
a measurement unit that measures the second signal received by the reception unit,
wherein the reception unit receives the second signal while the transmission unit applies the first signal.

2. The measurement device according to claim 1,
wherein application of the first signal performed by the transmission unit and reception of the second signal performed by the reception unit are performed with one common probe.

3. The measurement device according to claim 2, further comprising
a signal separation unit that separates the first signal and the second signal,
supplying the first signal to the probe via the signal separation unit, and
supplying the second signal output from the probe to the reception unit via the signal separation unit.

4. The measurement device according to claim 3,
wherein the signal separation unit is a duplexer.

5. The measurement device according to claim 3,
wherein the signal separation unit is a circulator.

6. The measurement device according to claim 1,
wherein a probe used for application of the first signal performed by the transmission unit is different from a probe used for reception of the second signal performed by the reception unit.

7. The measurement device according to claim 1,
wherein the reception unit receives the second signal including modulated noise obtained by modulating noise generated inside the object to be measured by the first signal, which has been applied to the object to be measured by the transmission unit.

8. The measurement device according to claim 1, further comprising
a movement control unit that moves at least one of a position where the transmission unit applies the first signal to the object to be measured and a position where the reception unit receives the second signal,
wherein the movement control unit sequentially changes the measurement position in a two-dimensional plane on the object to be measured.

9. The measurement device according to claim 8,
wherein the measurement unit displays information indicating the second signal measured at the measurement position on a display unit in association with the measurement position.

10. The measurement device according to claim 9,
wherein the measurement unit displays each piece of information indicating the second signal associated with each measurement position on the display unit in association with each measurement position by using a map of the two-dimensional plane.

11. The measurement device according to claim 10,
wherein the measurement unit displays each piece of information indicating the second signal on the display unit by using the map using an image representing a density corresponding to information indicating the second signal.

12. The measurement device according to claim 10,
wherein the measurement unit superimposes information indicating a boundary on the two-dimensional plane corresponding to each measurement position on the map, and displays the information on the display unit.

13. The measurement device according to claim 10,
wherein the measurement unit superimposes an image of the object to be measured on the map, and displays the image on the display unit.

14. A measurement method, comprising:
while a transmission unit applies a first signal formed by a high frequency signal to an object to be measured,
a reception unit receiving a second signal formed by a high frequency signal generated from the object to be measured; and
a measurement unit measuring the received second signal.
